(19) United States
(12) Patent Application Publication
(10) Pub. No.: US 2006/0011582 A1
(43) Pub. Date: Jan. 19, 2006

(54) Fast isotropic etching system and process for large, non-circular substrates

(76) Inventor: Stephen E. Savas, San Jose, CA (US)

Correspondence Address: EDWARD S. WRIGHT, 1100 ALMA STREET, SUITE 207, MENLO PARK, CA, 94025, US

(21) Appl. No.: 11/180,985

(22) Filed: Jul. 13, 2005

Related U.S. Application Data
(60) Provisional application No. 60/588,259, filed on Jul. 14, 2004.

(51) Int. Cl. C23F 1/00; H01L 21/306

(52) U.S. Cl. 216/67; 156/345.29; 156/345.33

(57) ABSTRACT

System and process for isotropic etching of organic or other films on large non-circular substrates for manufacture of flat panel displays or photovoltaic or other devices. The process can remove organic polymer or silicon-based material with a rate distribution that can be controlled to optimize process results. It does so while avoiding electrical charging of the workpiece and mobile metal contamination that could cause damage to the devices. The etching chamber employs at least one large plasma source which can be based on RF induction coupling or microwave coupling, with the plasma from the source being distributed through a reservoir and perforated screen or grid over the area of the large substrate. Fluorine-containing gases can be used for etching silicon-based materials, and oxygen, water vapor or hydrogen can be used for etching organic materials. Gases which accelerate or decrease the etching rate can be added to the etching gas to control the etching rate and the surface potential on the substrate. Additional radical sources feed the different regions of the reservoir above the perforated screen to adjust the etching rate on the substrate in the adjacent areas. One or more secondary sources of activated species located above different areas of the screens can be operated at different power levels to control the distribution of etching rate. This invention thereby permits varying etching rates of silicon-based materials or organic materials for different parts of the substrate as needed to finish removal in all areas of the substrate with the desired profile. The invention also provides for chemical conversion of inorganic residues normally remaining after the oxidation of the photoresist in the ashing process by addition of small amounts of halogenated gas(es) to the mixture flowing through the plasma sources. With the system and process of the invention, space efficiency, and cost per substrate for manufacturing large substrates used for various applications can be reduced significantly

### BACKGROUND OF THE INVENTION

### Field of Invention

This invention pertains to a novel method for isotropic etching of organic or other films on large non-circular substrates for manufacture of flat panel displays or photovoltaic or other devices.

### OBJECTS OF SUMMARY OF THE INVENTION

It is, in general, an object of the invention to provide a new and improved system and process for etching silicon-based or organic materials from large substrates while permitting better control of the etching rate and potential distribution across those substrates.

Another object of the invention is to provide a system and process of the above character in which the etching is done so that it avoids non-uniformity in etching and electrostatic potential on the surface of the substrate.

These and other objects are achieved in accordance with the invention by providing a system and process for etching a film on a large, non-circular substrate in which a primary gas mixture is fed to one or more primary plasma sources to produce reactive species which flow into a primary reservoir, the flow of species from the primary sources are passed through one or more permeable or perforated sheets of material which form a boundary between the primary reservoir and a volume adjacent to the substrate, a secondary gas mixture is fed to one or more smaller secondary plasma sources to produce accelerant or decelerant species that either accelerate or decelerate the etching rate of the film when it is also exposed to reactive species from the primary plasma source(s), and the accelerant ordecelerant species are passed through one or more distribution manifolds to distribute the accelerant or decelerant species preferentially into desired parts of the primary reservoir where they mix with the primary reactive species and then pass through the permeable or perforated sheets and cause the etching rate to be adjusted as desired in the corresponding areas of the substrate.

### BRIEF DESCRIPTION OF THE DRAWINGS

FIG. 1(a) is a cross-sectional view, somewhat schematic, of one embodiment of an etching reactor incorporating the invention.

FIG. 1(b) is a cross-sectional view, somewhat schematic, of another embodiment of an etching reactor incorporating the invention.

FIG. 2 is a cross-sectional view, somewhat schematic, of another embodiment of an etching reactor incorporating the invention.

FIG. 3 is a top plan view, illustrating the injection pattern for additive gases in the embodiments of FIGS. 1(a), 1(b) and 2.

FIG. 4 is a cross-sectional view, somewhat schematic, of another embodiment of an etching reactor incorporating the invention.

### DETAILED DESCRIPTION

It has been observed that the etching rate across large substrates varies in a gradually changing manner except at or near the corners or edges of rectangular substrates and peripheral regions of substrates with other shapes. It has also been found that both the etching rate and the surface potential on the substrate must be adjusted to achieve good uniformity for many types of substrate manufacturing technologies, and that inert gases or other gases which do not greatly affect etching rate can affect the electrical potential on the substrate surface. The invention provides a practical, relatively low cost apparatus and process for reducing the variation of both etching rate and surface potential across a large substrate.

The invention utilizes one or more primary induction-coupled plasma sources and one or more smaller secondary plasma sources to provide reactive species for etching of silicon-based or organic materials (including photoresist) from large substrates. Reactive species from the primary sources are fed to a primary reservoir which is similar in shape and proximate to the substrate. After passing through this reservoir, the species flow through a partially permeable barrier, grid or screen to etch material on the large substrate.

The grid or screen thus separates the primary reservoir from the region adjacent to the substrate while allowing neutral reactive species to flow from the reservoir to the substrate to etch material on it. The grid can consist of single or multiple, gapped thin plates that are perforated to allow neutral species to pass through. Such plates can be made of quartz, ceramic, or metal. Most radicals for stripping across much or all of the substrate comes from one or a group of induction plasma sources that is/are fed a primary etching gas(es) or mixture. A second mixture or gas can be fed to the second set of sources which feed the reactive species they make into the primary reservoir where they mix with the species from the primary source(s).

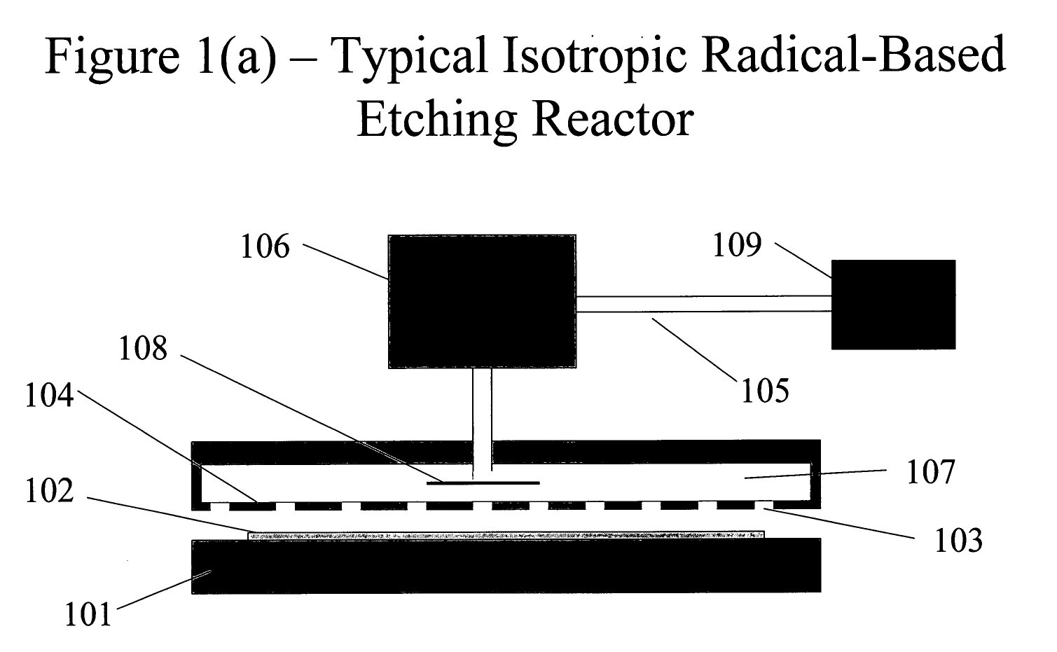

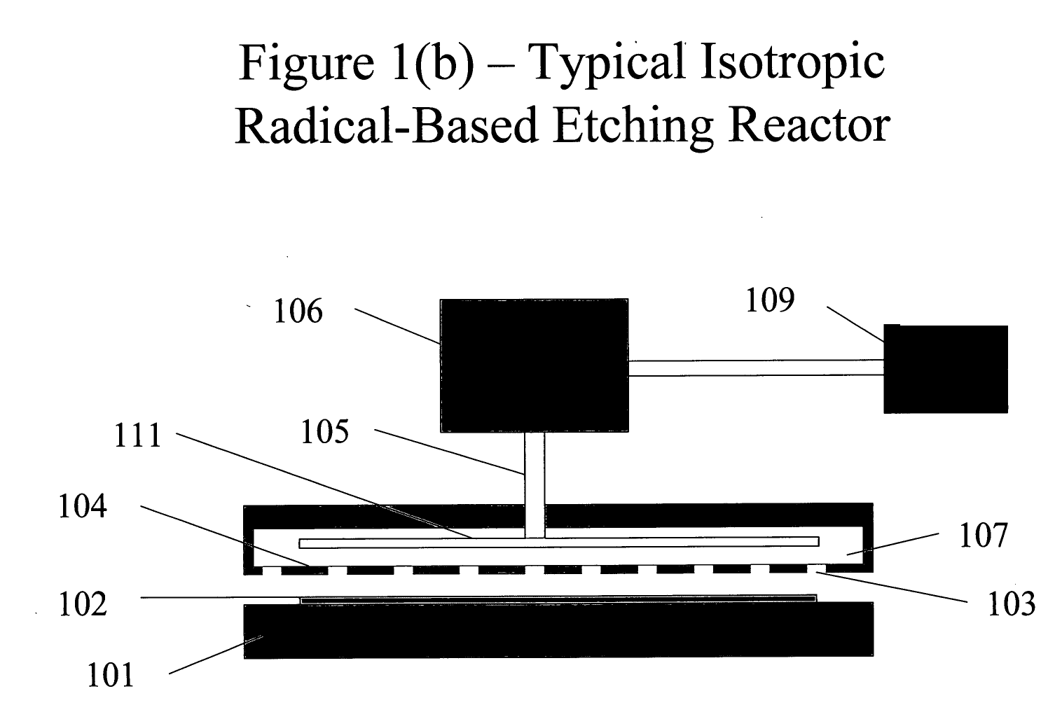

FIG. 1(a) illustrates a typical isotropic etching or stripping system which is fed from an inductively coupled plasma source. This system includes a pedestal 101 for holding a substrate 102 roughly parallel to a screen 104, with a plasma source 106 for supplying reactive species to a reservoir 107 on the side of the screen opposite the substrate. The reactive species flow from the reservoir to the substrate through holes 103 in the screen.

Gas is supplied to the plasma source from through a tube 105 from a source 109 which includes a set of metering valves. A baffle 108, shown in the form of a simple disk, is aligned with the outlet of the tube to prevent the reactive species from impinging directly on the holes which are aligned with the tube and thereby prevent excessive flow through those holes.

The embodiment shown in FIG. 1(b) is similar to that of FIG. 1(a), with the addition of a manifold 111 within the reservoir 107 for distributing activated species from the source to the interior of the reservoir. Like reference numerals designate corresponding elements in the two embodiments.

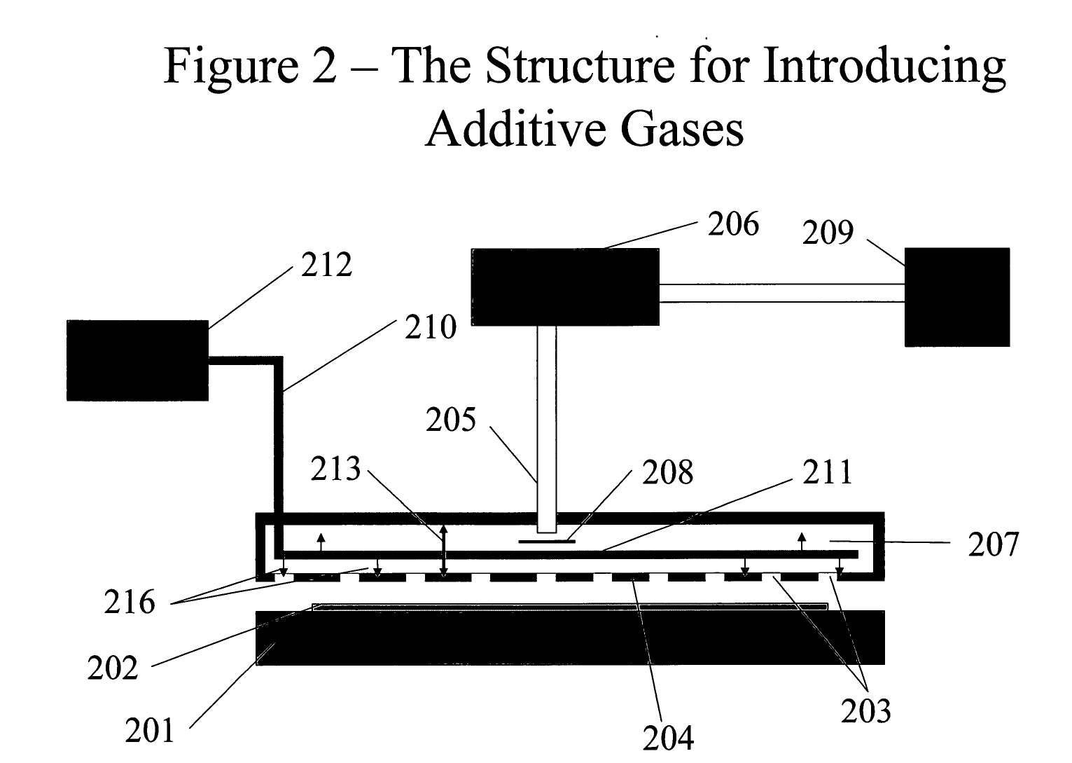

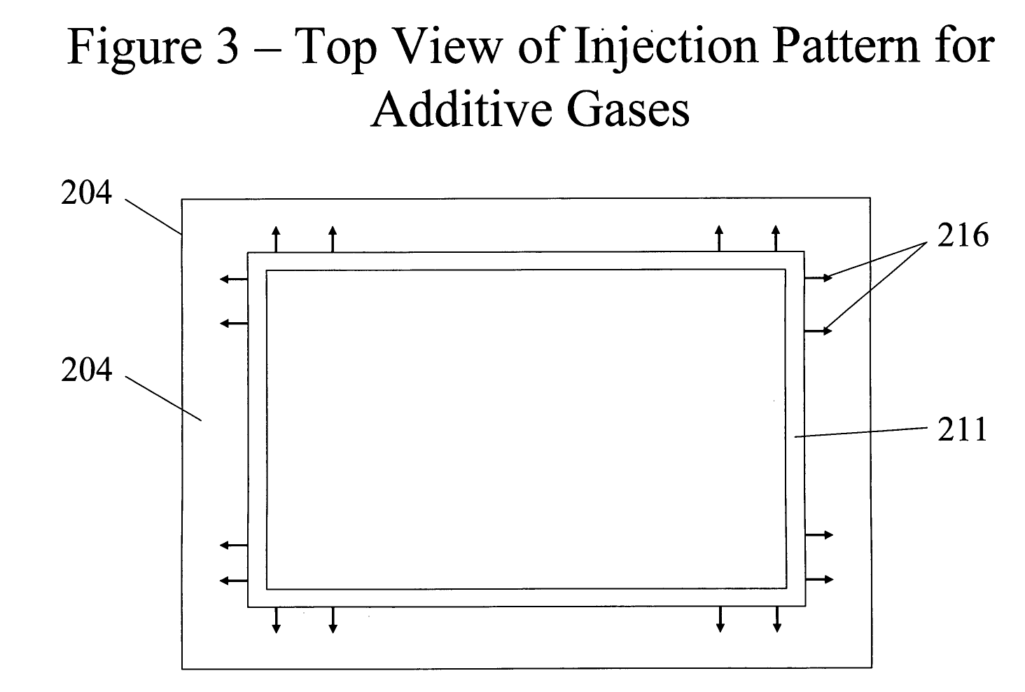

In the embodiment of FIGS. 2 and 3, a pedestal 201 supports a substrate 202 in facing relationship with a grid or screen 204 with holes 203 through which reactive species are injected into the region between the reservoir and the pedestal. A plasma source 206 supplies primary reactive species through a duct 205 to a reservoir 207 on the side of the screen opposite the substrate, and a baffle 208 aligned with the outlet of the duct helps to distribute those species for a more even flow throughout the reservoir. Gas is supplied to the reactive species source from a gas source 209.

An additional reactive species injector 211 is disposed within the showerhead reservoir 207 and fed with activate species from a secondary reactive species source 209 via a duct 210. As best seen in FIG. 3, injector 211 is in the form of a generally rectangular manifold or distribution tube which extends along a path near the side walls of the reservoir, with discharge openings or holes for delivering the additional reactive species into the corner regions of the reservoir, as indicated by arrows 216 are shown as arrows such as those labeled 216. The supplemental species from the additional injector are not injected uniformly within the reservoir, but instead are more concentrated in the more remote regions such as the corners of a rectangular substrate which otherwise would not receive as much reactive species as other regions of the substrate.

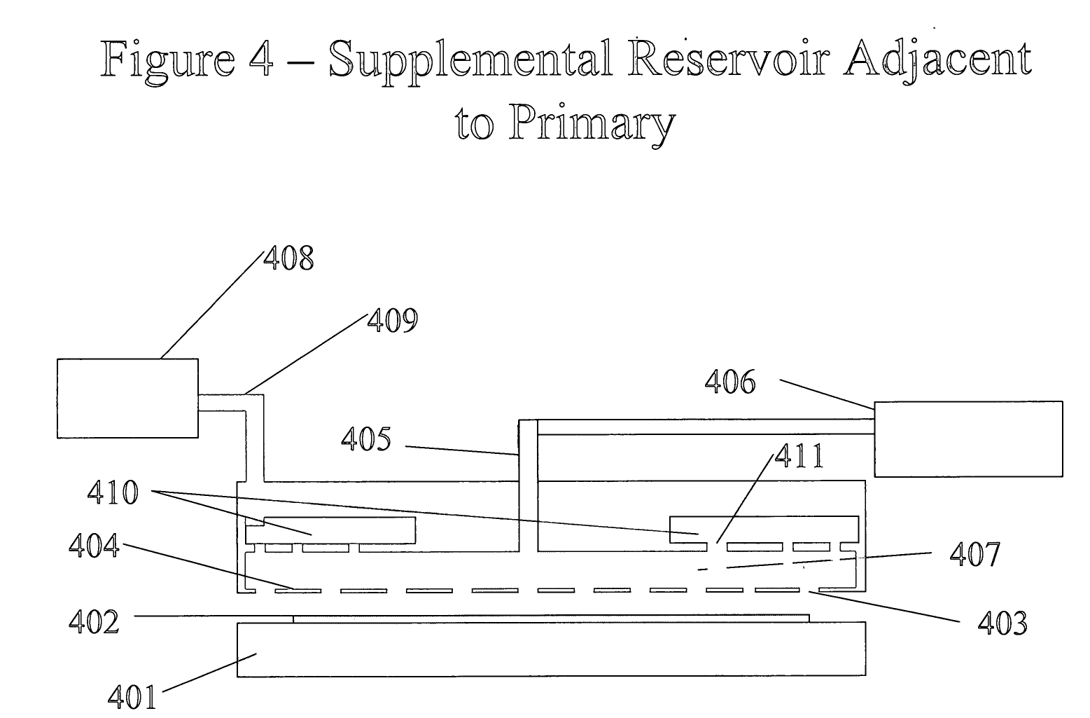

The embodiment of FIG. 4 has an injector for additive reactive species is in the form of a secondary reservoir 410 behind a primary reservoir 407. If desired, a plurality of secondary reservoirs can be linked and cover as much as virtually the entire area of the primary reservoir. A pedestal 40 holds a substrate 402 at a substantially evenly spaced distance from a screes 404 which has openings or holes 403 that permit the active species to pass from the primary reservoir to the substrate. Primary reactive species are supplied by one or more sources 406 through tube 405 to primary reservoir 407. Supplemental reactive species are supplied to the primary reservoir from secondary reservoir 410, which is supplied separately with additive reactive species from a separate source 408 via a duct 409. A screen between the secondary and primary reservoirs has one or more openings or holes 41 which distribute the supplemental species into the primary reservoir to mix with the primary species before injection into the plasma discharge.

Different gases or mixtures can be fed to the different sets of sources. For silicon based etching, the main etching gas can be a fluorine-containing gas, while for organic etching or photoresist removal the main gas is a oxygen, hydrogen and/or water vapor based mixture. The gas feed to the main source(s) can also include an additional flow of inert gas and/or other additives such as nitrogen, carbon dioxide or hydrogen containing gases. For etching either type of material, additive gases can be injected to either accelerate or reduce the etching rate. For decreasing the etching rates of silicon-based materials, one can add hydrogen or gases which contain hydrogen such as hydrocarbons, alcohols or ammonia. For accelerating the etching rate of silicon-based materials, one can add oxygen or other gas such as nitrous oxide or ozone. For decelerating the etching rate of organic materials, the additive gas can include hydrocarbons, ammonia, alcohols or other organic gases or substantial amounts of nitrogen. For accelerating the etching rate of organics, small amounts of gases containing fluorine such as Sulfur Hexafluoride, hexafluoroethane or other fluorine containing gases, or nitrous oxide, water vapor can be used.

For controlling electrical potential on the surface of the substrate gases such as argon, helium, nitrogen, water vapor or halogen-containing gases can be added either to the supply for the primary sources or to the supply to the secondary sources.

To achieve high rate etching on large substrates, multiple large plasma sources which receive flows of reactant gases and provide the bulk of the reactive species directly to the primary reservoir can be employed. The primary reservoir feeds reactive species through a screen consisting of one or more grids or baffles to the substrate to be processed. The secondary sources which have independent and separately controlled gas supplies and electric power can be fed gases which either accelerate or slow the etching rate or control the potential. These sources can feed their reactive species first to a set of secondary reservoirs or ducts which, in turn, discharge the reactive species into areas of the primary reservoir corresponding to the areas of the panel where etching rates need to be accelerated or slowed. If desired, additional levels of sources and reservoirs can be included for feeding reactive species to the primary reservoir. These different sources of reactive species permit the process to achieve the desired rate distribution across the substrate. The secondary and additional sets of plasma can be either microwave or induction coupled.

With a rectangular substrate, for example, the secondary and additional sets of sources would provide supplemental reactive species to the corner and edge areas of the primary reservoir. Since the etching rate at the corners is typically slower than in the center, the secondary sources might be supplied with a gas such as nitrous oxide to accelerate etching. Since the substrate surface potential can be different near the corners, an additive gas such as argon might also be added to the flow to secondary sources to adjust the potential in those areas. Thus, independently controlled gas mixtures are provided to independently controlled sources which feed into the primary reservoir proximate to each of the four corner regions of the substrate.

Secondary sources feeding the corner regions can be smaller and supplied with less, and possibly different gases than the primary sources. The supply of suppressor or accelerator gases and inert diluent gases to each of the secondary sources and thence to the corner regions is entirely independent of the supply to the primary sources and to the central portion of the substrate. Consequently, the stripping rate and potential on the surface of the substrate can be adjusted to provide both a simultaneous ending of the etching or ashing across the substrate and a uniform surface potential.

In general, the operating pressures of the primary, secondary and additional levels of source must be close to each other. Suitable operating pressures for these types of sources range from a few hundred milliTorr to about 10 Torr. The pressure should generally be such that reactive species flow rapidly to the substrate without excessive loss of the species by recombination. The rate of flow of gas to the primary sources is generally on the order of about one standard liter per minute to a few hundred standard liters per minute for each square meter of substrate area, with higher etching rates generally requiring higher gas feed flow rates.

With one or more additional injectors within the reservoir, it is possible to take advantage of the symmetry of the substrate and utilize a smaller number of secondary sources. As noted above the secondary species introduced through those injectors can include species for either accelerating or decreasing the etching rate, or for controlling the electrical potential on the surface of the substrate. The flows of the feed gases to the secondary sources are controlled by their own flow rate controllers and can therefore be varied independently of the flows of the main etching reactant gases injected into the primary sources. FIGS. 2 and 3 illustrate the use of a single additional injector to direct supplemental species to all four of the corner regions of a rectangular substrate, and only there, to boost the etching rate. If the etching rate also needs to be increased or decreased in greater or lesser degree in other regions, an additional source and injector could distribute appropriate species to those regions in a symmetrical manner.

If desired, the position and hole patterns of the supplemental gas injector manifold(s) can be adjusted, iteratively if necessary, to adjust the distribution of the activated species and, hence, the etching rate in a given region to provide the desired results. That can be done without other changes to the showerhead structure or reservoir. It is possible to make the depth of the reservoir, indicated by arrow 213 in FIG. 2, greater or lesser in order to control the extent to which the supplemental species spread out prior to flowing into the discharge volume. In general, making the depth of the reservoir smaller will reduce the extent of such spreading or diffusion prior to flow into the discharge. Thus, this structure is very flexible in permitting the etching pattern to be to be adjusted to optimize performance.

With one or more secondary reservoirs behind the primary reservoir and separated from it by a permeable or perforated barrier, an appropriate choice of the hole pattern in either of the structures for introduction of the additive species into the primary reservoir can be made by testing the optimized uniformity pattern for etching rate or for electrical potential on a substrate. Once the non-uniformity of either parameter has been measured, it could be adjusted by a process of iteration, making suitable adjustments in the hole pattern so as to affect the spatial distribution of the additive species. With rectangular substrates, for example, the introduction of additive gases near the corners can accelerate the etching rate in those regions by as much as 10% to 50%.

Gases such as O₂ or N₂O have been found to be particularly suitable for accelerating the etching of silicon and silicon-containing materials where the primary etching gases are fluorinated gases such as fluorocarbon gases (CF₄, C₂F₆, C₃F₈, CHF₃) and partially hydrogenated fluorocarbon gases. Suitable gases for decreasing etching rate of silicon and silicon-containing compounds include hydrogen-containing gases such as CH₄, C₂H₆, and other hydrocarbons. Other rate decreasing gases can include nitrogen, ammonia, alcohols or hydrogen-cyanide. Etch rate accelerating gases for etching organic polymers can include nitrogen gas (N₂) in small amounts, fluorine-containing gases (e.g., SF₆, C₂F₆, NF₃ and the like), water vapor or N₂O. Rate decreasing gases for etching organic polymers include hydrogen and/or carbon-containing gases such as hydrocarbons and other volatile organic compounds including alcohols, ammonia, or diluents such as helium or argon. Additive gases for reducing the surface potential include argon or helium, and additive gases for increasing the surface potential include nitrogen, carbon dioxide or highly electronegative gases such as SF₆ or CL₂.

Whether the structure for injecting the additive species is internal or external to the primary reservoir, the additive species is injected into the primary reservoir so that it mixes with the primary species before that mixture flows into the discharge region. This avoids reliance upon mixing of the additive species in the discharge region adjacent to the substrate. Inadequate mixing might cause anomalous behavior of the discharge in some regions if additive gases were injected directly into them. It also avoids the need to control additional flows of the etching gases into those regions where additive gases were also to be used, as required in the prior art. The invention is thus able to improve etch rate uniformity more effectively and more economically than systems heretofore provided.

Moreover, the invention is able to address and remedy the non-uniformity of the surface electrical potential on the substrate that can have a serious adverse impact on the yield of devices. The supplemental reactive species injected from the additional injectors mix with the primary reactive species prior to injection into the discharge. Generally, the flow pattern of the primary species depends on the way they are injected into the primary reservoir. Such primary species may be injected by means such as shown in FIG. 2 where the injection is central in the primary reservoir or by an injector tube having perforations. In the case of the central injector, the bulk motion of the primary species is generally outward from the point of introduction. In this case, any supplemental species introduced by additional injectors will mix with and flow with the primary species after introduction into the primary reservoir. If desired, the primary species may be injected into the primary reservoir with a manifold which delivers it closer to the regions from which it is to be discharged. In that case, there may be less bulk motion of the primary species which may cause the supplemental species to be less widely dispersed within the primary reservoir prior to flowing into the discharge.

Generally, the hole pattern in the additional reactive species injectors can be chosen to suitably mix and disperse the supplemental species so that they are appropriately distributed in the desired area of the primary reservoir.

It is apparent from the foregoing that a new and improved system and process for isotropic etching of organic or other films on large non-circular substrate have been provided. While only certain presently preferred embodiments have been described in detail, as will be apparent to those familiar with the art, certain changes and modifications can be made without departing from the scope of the invention as defined by the following claims.

1. A system for etching a film on a large, non-circular substrate, comprising: a primary reservoir,
one or more primary plasma sources that are fed with a primary gas mixture to produce reactive species that flow into the primary reservoir,
one or more permeable or perforated sheets of material which form a boundary between the primary reservoir and the volume adjacent to the substrate and permit flow of species from the primary sources into the volume adjacent to the substrate,
one or more smaller secondary plasma sources which are fed with a secondary gas mixture to produce (accelerant or decelerant) species that either accelerate or decelerate the etching rate of the film when it is also exposed to reactive species from the primary plasma source(s), and
one or more distribution manifolds that distribute the accelerant or decelerant species preferentially into desired parts of the primary reservoir where they mix with the primary reactive species and then pass through the permeable or perforated sheets and cause the etching rate to be adjusted as desired in the corresponding areas of the substrate.

2. The system of claim 1 wherein the primary gas mixture contains an inert gas that locally affects the electrical potential of the plasma on the surface of the substrate.

3. The system of claim 1 wherein the secondary gas mixture contains species for adjusting the electrical potential in selected areas on the surface of the substrate.

4. A process for etching a film on a large, non-circular substrate, comprising the steps of:
feeding a primary gas mixture to one or more primary plasma sources to produce reactive species which flow into a primary reservoir,
passing the flow of species from the primary reservoir through one or more permeable or perforated sheets of material which form a boundary between the primary reservoir and a volume adjacent to the substrate,
feeding a secondary gas mixture to one or more smaller secondary plasma sources to produce accelerant or decelerant species that either accelerate or decelerate the etching rate of the film when it is also exposed to reactive species from the primary plasma source(s), and
passing the accelerant or decelerant species through one or more distribution manifolds to distribute the accelerant or decelerant species preferentially into desired parts of the primary reservoir where they mix with the primary reactive species and then pass through the permeable or perforated sheets and cause the etching rate to be adjusted as desired in the corresponding areas of the substrate.

5. The process of claim 4 wherein the primary gas mixture contains an inert gas that locally affects the electrical potential of the plasma on the surface of the substrate.

6. The system of claim 4 wherein the secondary gas mixture contains species for adjusting the electrical potential in selected areas on the surface of the substrate.
